(19) United States
(12) Patent Application Publication
(10) Pub. No.: US 2012/0298163 A1
(43) Pub. Date: Nov. 29, 2012

(54) THERMOELECTRIC UNIT

(76) Inventors: Holger BREHM, Erdmannhausen (DE); Thomas Himmer, Reichenbach (DE); Thomas Heckenberger, Leinfelden-Echterdingen (DE); Rudolf Riedel, Pforzheim (DE)

(21) Appl. No.: 13/525,662

(22) Filed: Jun. 18, 2012

Related U.S. Application Data
(63) Continuation of application No. PCT/EP2010/069784, filed on Dec. 15, 2010.

(30) Foreign Application Priority Data
Dec. 16, 2009 (DE) 10 2009 058 674.1

(51) Int. Cl. H01L 35/32

(52) U.S. Cl. 136/210

(57) ABSTRACT

A thermoelectric unit for electrically interconnecting a plurality of thermoelectric modules. The thermoelectric unit includes a first thermoelectric module having a plurality of interconnected thermoelectric elements, the first thermoelectric module being interposed between a main surface of an inner flat tube and a main surface of an outer flat tube of a double-walled cooling tube, a second thermoelectric module being interposed between a second main surface of the inner flat tube and a second main surface of the outer flat tube of the double-walled cooling tube and/or between a main surface of an inner flat tube and a main surface of an outer flat tube of a second double-walled cooling tube, and an electrical connector designed to connect the first thermoelectric module to the second thermoelectric module in an electrically conducting manner.

This nonprovisional application is a continuation of International Application No. PCT/EP2010/069784, which was filed on Dec. 15, 2010, and which claims priority to German Patent Application No. DE 10 2009 058 674.1, which was filed in Germany on Dec. 16, 2009, and which are both herein incorporated by reference.

### BACKGROUND OF THE INVENTION

1. Field of the Invention

The present invention relates to a thermoelectric unit

2. Description of the Background Art

The energy stored in exhaust gas in the form of heat has hitherto been discharged into the environment unused. In order to increase the effectiveness of a system, e.g., a vehicle, and consequently to reduce the discharge of CO₂ in operation, a thermoelectric generator (TEG) can be implemented, the thermoelectric module (TEM) of which converts part of the heat into electric energy and feeds it back into the system. The TEG can be accommodated with different use at any point in the exhaust gas system or in the exhaust gas recirculation. Current-operated, the TEG can also be used as a thermoelectric heater or cooler (TE-HC).

EP 1 475 532 A2, which corresponds to U.S. Pat. No. 7,100,369 discloses a thermoelectric generator with a thermoelectric element, which uses the exhaust gas from an engine as a high-temperature heat source and an engine coolant as a low-temperature heat source to generate electricity. A valve regulates the supply of the exhaust gas to the thermoelectric element according to the load of the engine.

Conventional TEMs according to the prior art are not optimally suitable for use in a TEG due to their design and joining technique and also are less effective. Furthermore, the TEMs must be electrically connected and integrated in an optimal manner.

Conventional TEGs are less efficient due to the increased heat transmission resistance between thermoelectrically active materials and a heat source/heat sink. An integration of the TEM into a heat exchanger has also proven to be impractical. Joining techniques hitherto available are sometimes not high-temperature stable. Furthermore, on the gas-side contact of the TEM in the heat exchanger there is often only a low heat transfer. According to the prior art, accordingly conventional TEMs are not optimally suitable for use in a TEG due to their design and joining technique and are less effective. The electrical connection is often complex and unstable.

### SUMMARY OF THE INVENTION

It is therefore an object of the present invention to provide an improved thermoelectric unit.

The present invention is based on the realization that a larger quantity of thermoelectric modules can be very easily connected to one another by a favorable design of the electrical connection contacts. In this manner the advantages of the thermoelectric elements can be efficiently utilized even with compact heat exchangers.

The present invention creates a thermoelectric unit for the electrical connection of a plurality of thermoelectric modules, wherein the thermoelectric unit has the following features: a first thermoelectric module, which has a plurality of thermoelectric elements interconnected to one another, wherein the first thermoelectric module is arranged between a main surface of an inner flat tube and a main surface of an outer flat tube of a double-walled cooling tube; a second thermoelectric module, which has a plurality of thermoelectric elements interconnected to one another, wherein the second thermoelectric module is arranged between a further main surface of the inner flat tube and a further main surface of the outer flat tube of the double-walled cooling tube and/or between a main surface of an inner flat tube and a main surface of an outer flat tube of a further double-walled cooling tube; and an electrical connector, which is embodied to connect the first thermoelectric module to the second thermoelectric module in an electrically conducting manner.

The thermoelectric modules (or TEM for short) can be used, e.g., in a heat exchanger. The heat exchanger can be used in a vehicle either as a thermoelectric generator or as a thermoelectric heater and cooler. For example, with a use of the heat exchanger as a thermoelectric generator or TEG, two differently temperature-controlled and spatially separated media or fluids are guided past one another such that an electric current is generated in the thermoelectric modules. The thermoelectric elements can be, for example, differently doped semiconductor materials. The thermoelectric elements can be arranged as a plurality of blocks between the main surfaces of the inner and outer flat tube and have electric conductors via which the individual blocks are connected to one another in an electrically conducting manner. A double-walled cooling tube thus in general has two thermoelectric modules or TEMs arranged one above the other viewed in cross section. The double-walled cooling tube can thus also be referred to as a TEM tube. The double-walled cooling tube can have, e.g., a rectangular cross section, thus can be composed of an inner rectangular tube and an outer rectangular tube surrounding it. The main surfaces of the inner flat tube and of the outer flat tube are thus the larger areas of the inner and outer rectangular tube lying opposite one another. For example, one of the two differently temperature-controlled fluids of the heat exchanger is guided inside the inner tube of the TEM tube. This can be, e.g., a coolant from the engine cooling circuit of the vehicle. The other of the two differently temperature-controlled fluids can be, e.g., exhaust gas from an internal combustion engine of the vehicle and be guided on an outside of the outer tube of the double-walled cooling tube. As a result of the temperature difference of the two media, current can be generated in the thermoelectric modules arranged between the inner tube and the outer tube. In general a heat exchanger has a plurality of double-walled cooling tubes arranged e.g., in a layered manner with respectively one thermoelectric module in each intermediate space between the main surfaces of the inner and outer flat tubes. The electrical connectors can be differently shaped and electrically conducting metal elements. These can be embodied in order to connect the two thermoelectric modules inside a double-walled cooling tube and at the same time or alternatively to connect them to the thermoelectric modules of a further double-walled cooling tube in an electrically conducting manner.

According to an embodiment, the inner flat tube of the double-walled cooling tube can have a greater length than the outer flat tube of the double-walled cooling tube and the inner flat tube of the further double-walled cooling tube can have a greater length than the outer flat tube of the further double-walled cooling tube, such that at least on one side the ends of the inner flat tubes project beyond the corresponding ends of the outer flat tubes, wherein the electrical connector extends from the projecting end of the inner tube of the double-walled cooling tube to the projecting end of the inner tube of the further double-walled cooling tube. Advantageously, conductor connections for the electrically conducting connection of thermoelectric modules of a plurality of cooling tubes can be positioned and fixed in a simple manner.

For example, the electrical connector can be embodied as a one-part clamp, which laterally spans the inner flat tube on a lateral surface of the double-walled cooling tube, wherein a first end of the connector contacts the first thermoelectric module of the double walled cooling tube and a second end or an intermediate contact of the connector contacts the further thermoelectric module of the double-walled cooling tube. An electrical connector of this type can be produced simply and cost-effectively and is easy to use. The contacting can be carried out, e.g., via an insertion of the end and of the second end or of the intermediate contact between one of the elements of the thermoelectric module and the inner flat tube. The one-piece clamp can bear entirely against the inner flat tube or can be spaced apart from a lateral surface of the inner flat tube.

According to a further embodiment, the electrical connector can be embodied as a one-part multiple connector clamp, which laterally spans the inner flat tube of the double-walled cooling tube and the inner flat tube of the at least one further double-walled cooling tube on one lateral surface, wherein the multiple connector clamp is embodied in order to connect two thermoelectric modules assigned to the double-walled cooling tube to at least one thermoelectric module of a further double-walled cooling tube. In this embodiment the electrical connector can also be produced simply and cost-effectively and is easy to place and to attach, in particular when it is necessary to connect the thermoelectric modules of several cooling tubes.

The electrical connector can also be embodied as a multipart clamp, of which a first part spans a lateral surface of the inner flat tube of the double-walled cooling tube and at least one second part spans the inner flat tube of a further double-walled cooling tube on a lateral surface, wherein the first part and the second part can be connected positively in order to connect in an electrically conducting manner at least one thermoelectric module assigned to the double-walled cooling tube to at least one thermoelectric element assigned to the further double-walled cooling tube. For example, the one part and the at least one further part can be embodied as hooks that can engage in one another. This embodiment provides the advantage that, due to the separate steps of the positioning and connecting of the at least two parts of the clamp, an attachment and removal of the electric connector can be facilitated.

According to a further embodiment, the electrical connector can be spanned by a narrow side of the inner tube and have a bushing in the region of a subsidiary surface of the inner tube connecting the main surfaces of the inner tube, which bushing can be embodied to be connected to an insert conductor in an electrically conducting manner. The insert conductor can be, e.g., an electrically insulated copper cable or a conductor clamp, with which individual TEM tubes can be connected or a connection can be produced to an external power supply. This makes it possible to quickly contact the individual thermoelectric modules even over several cooling tubes.

The outer flat tube of the double-walled cooling tube can also have a first opening and, on a main surface of the outer flat tube of the further double-walled cooling tube, have a second opening, which is arranged at a position lying opposite the first opening and wherein the electrical connector is embodied as a pin plug, which is guided through the first opening and the second opening. By means of such openings in connection with pin plugs, there is a particularly space-saving possibility of connecting thermoelectric modules in an electrically conducting manner.

According to an embodiment, the pin plug can have a non-conducting sheath. The plug connector can be embodied as a double plug or a conductor pin with an electrically conducting core and an electrically insulated sheath, so that an improved electrical insulation of the contact between the thermoelectric modules and an environment is ensured. Particularly with adverse environmental conditions of the thermoelectric unit, such as in vehicle use, this will lead to an increased service life of the same.

According to a further embodiment, the electrical connector can have a first part, which can be embodied as a prong connected to the thermoelectric module in an electrically conducting manner, which prong projects out of an opening of a main surface of the outer flat tube of the double-walled cooling tube and wherein the electrical connector furthermore can have a second part which likewise can be embodied as an electrically conducting prong, wherein the second part is connected to a second thermoelectric module in a conducting manner, which is assigned to a further double-walled cooling tube, and wherein the second part projects out of an opening of a main surface of the outer flat tube of the second double-walled cooling tube. The first and the second part of the electrical connector can be in electrically conducting contact with one another. For the electrical connection of the thermoelectric module to a further thermoelectric module, the double-walled cooling tube can thereby be arranged closely adjacent to a further double-walled cooling tube such that the prongs connected to the respective thermoelectric module can contact one another. Here too an electric insulation of the prong with respect to the surrounding medium can be provided, whereby the advantages referenced above in turn can be achieved.

The electrical connector can also be embodied as a cable, the end of which can be connected through an opening of a main surface of the outer flat tube of the double-walled cooling tube to the thermoelectric module in an adhesive and electrically conducting manner. With this embodiment, the required material expenditure can be kept particularly low, wherein a secure electrical contacting of the individual thermoelectric modules is also guaranteed by the adhesive connection. In contrast, a production expenditure for a connection of this type will be higher than a production and attachment expenditure for the connection to a correspondingly shaped clamp.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIGS. 1 through 7 illustrate isometric images of one-part or two-part outer flat tubes or inner flat tubes of a TEM tube, according to exemplary embodiments of the present invention;

FIGS. 8 and 9 illustrate isometric images of outer flat tubes with openings according to exemplary embodiments of the present invention;

FIG. 10 illustrates an isometric image of a thermoelectric module according to an exemplary embodiment of the present invention;

FIG. 11 illustrates an isometric image of an inner flat tube equipped with TE materials according to an exemplary embodiment of the present invention;

FIG. 12 illustrates an isometric image of a TEM tube equipped with TE materials according to an exemplary embodiment of the present invention;

FIG. 13 illustrates a section of a TEM tube equipped with TE materials in a sectional image according to an exemplary embodiment of the present invention;

FIG. 14 illustrates a detailed section of a TEM tube equipped with TE materials in a sectional image according to an exemplary embodiment of the present invention;

FIG. 15 through 17 illustrate isometric images of TEM tube covers according to exemplary embodiments of the present invention;

FIGS. 18 and 19 illustrate isometric images for connecting a TEM tube cover to a TEM tube according to exemplary embodiments of the present invention;

FIG. 20 illustrates an exploded view for the assembly of a TEG according to an exemplary embodiment of the present invention;

FIGS. 21 and 22 illustrate sectional images of an arrangement of an inner flat tube compared to an outer flat tube according to exemplary embodiments of the present invention;

FIGS. 23 through 26 illustrate images of TEM tubes with bases in section according to exemplary embodiments of the present invention;

FIG. 27 illustrates an isometric partial image of TEM tubes connected to bases according to an exemplary embodiment of the present invention;

FIG. 28 illustrates an isometric partial image of an inner flat tube with TE modules and conductor connector according to an exemplary embodiment of the present invention;

FIG. 29 illustrates a partial image in section of the inner flat tube with TE modules and conductor connector from FIG. 28;

FIG. 30 illustrates a partial image in section of the inner flat tube with TE modules and conductor connector according to a further exemplary embodiment of the present invention;

FIG. 31 illustrates an isometric image of a conductor connector with bushing according to an exemplary embodiment of the present invention;

FIG. 32 illustrates an isometric representation for an interconnection of TEM inner flat tubes via conductor connection according to an exemplary embodiment of the present invention;

FIG. 33 illustrates an isometric image of a two-part conductor connector according to an exemplary embodiment of the present invention;

FIGS. 34 through 36 illustrate isometric images and a sectional image for an interconnection of TEM tubes with two-part conductor connector according to an exemplary embodiment of the present invention;

FIG. 37 illustrates an isometric image of a conductor connector according to a further exemplary embodiment of the present invention;

FIGS. 38 and 39 illustrate isometric partial images for a connection of TEM tubes to the conductor connector from FIG. 37 according to an exemplary embodiment of the present invention;

FIG. 40 illustrates an isometric image of an insert conductor according to an exemplary embodiment of the present invention;

FIG. 41 illustrates an isometric partial image of an inner flat tube with the insert conductor from FIG. 40;

FIG. 42 illustrates an isometric image of an insert bushing according to a further exemplary embodiment of the present invention;

FIG. 43 illustrates an isometric partial image of a TEM inner flat tube with the insert bushing from FIG. 42;

FIG. 44 illustrates an isometric image of a two-part insert bushing according to a further exemplary embodiment of the present invention;

FIG. 45 illustrates an isometric partial image of a TEM inner flat tube with the two-part insert bushing from FIG. 44;

FIG. 46 illustrates an isometric image of a TEM tube plug connector according to an exemplary embodiment of the present invention;

FIG. 47 illustrates an isometric image for a connection of a TEM tube to the TEM tube plug connector from FIG. 46 according to an exemplary embodiment of the present invention;

FIGS. 48 and 49 illustrate an isometric image and a sectional partial image for an interconnection of TEM tubes via TEM tube plug connectors according to an exemplary embodiment of the present invention;

FIGS. 50 and 51 illustrate an isometric image and a sectional partial image for an interconnection of TEM tubes via conductor jointing sleeves according to an exemplary embodiment of the present invention;

FIGS. 52 through 54 illustrate isometric or sectional images for an interconnection of TEM tubes with a conductor pin according to an exemplary embodiment of the present invention;

FIG. 55 illustrates a sectional image for a connection of a TEM tube via a soldered cable according to an exemplary embodiment of the present invention;

FIG. 56 illustrates an isometric image of a TEM tube with a tube profiling produced by shaping according to an exemplary embodiment of the present invention; and

FIGS. 57 through 59 illustrate an isometric image and a sectional image for filled shaped tube profiles or a shaped tube profile covered with sheet metal according to exemplary embodiments of the present invention.

### DETAILED DESCRIPTION

In the following description of favorable exemplary embodiments of the present invention the same or similar reference characters are used for the elements shown in the various drawings with similar action, a repeated description of these elements being omitted.

A TEM tube according to the exemplary embodiments of the invention presented here is formed by a two-walled rectangular tube, wherein TE-active materials are introduced into an intermediate space of the two walls. An inner tube of the TEM tube is in contact with one of two fluids flowing through a TEG, an outer tube of the TEM tube is in contact with the other of the two fluids flowing through the TEG.

Various exemplary embodiments for inner and/or outer tubes of the two-walled rectangular tube are shown in FIGS. 1 through 9.

Thus FIG. 1 shows in an isometric image a one-part outer tube or outer flat tube 8 for use in a TEG. The outer flat tube 8 has a nonconductor 15 in an interior. A main surface directed outwards of the outer flat tube 8 is provided with a profile 20.

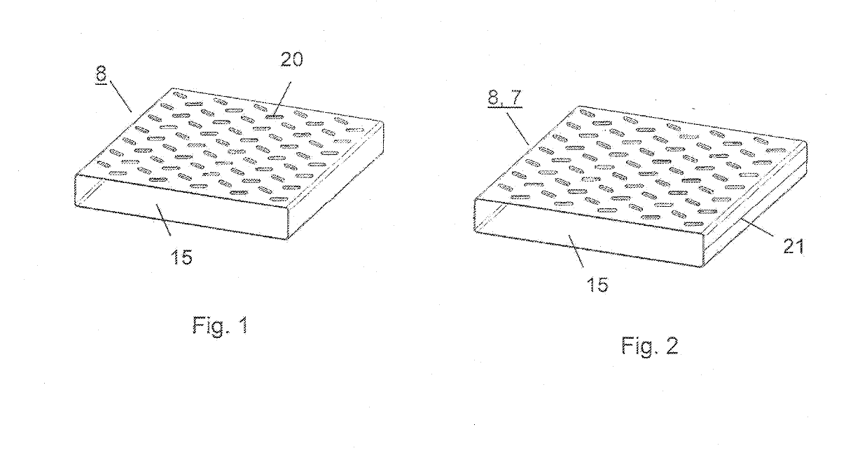

FIG. 2 shows in a further isometric image a similar exemplary embodiment of a profiled one-part outer tube 8, wherein here the tube 8 has a seam 21 in a side surface of the tube 8. The tube shown in FIG. 2 can also be used as an inner tube 7 for a two-walled tube.

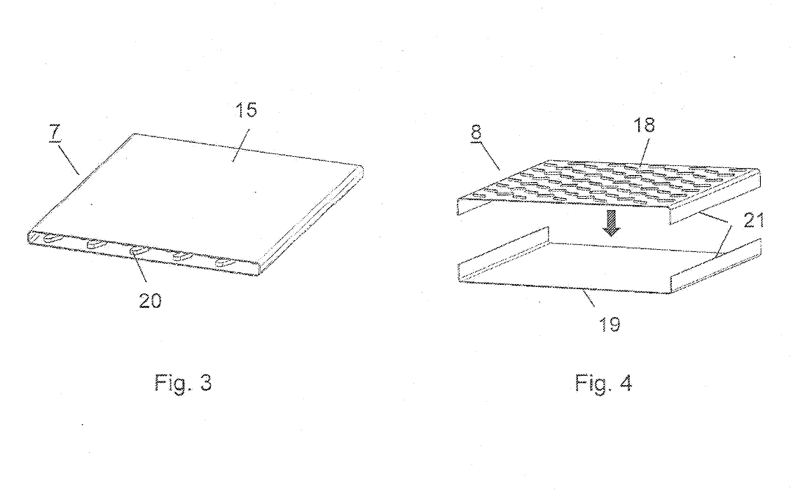

FIG. 3 shows in an isometric image an exemplary embodiment of a one-part inner tube 7 with a nonconductor 15 and a profile 20.

The inner 7 as well as the outer tube 8 is produced essentially from a metallic material, preferably of a stainless steel, e.g., 1.4404. However, an aluminum or copper material for lower use temperatures is also conceivable.

The two tubes 7, 8 are covered in part or entirely with an electrically non-conducting material 15 at least on their sides facing towards an intermediate space between the tubes 7, 8, so that TE material and tubes 7, 8 or electrical conductor and tubes 7, 8 are electrically insulated with respect to one another. This non-conducting material 15 can be, for example, a ceramic coating or a ceramic sheet 15. The non-conducting material 15 can be applied, for example, via a soldering or sintering process, wherein to this end the tubes 7, 8 can be pretreated in a different manner. For example, the tubes 7, 8 can be electroplated or printed, or they can also be equipped with an additional coating, e.g., of tungsten or silver.

The outer tube 8 and/or the inner tube 7 can have the profile 20 on a respective side assigned to a fluid. In the exemplary embodiments shown in FIGS. 1 through 9, the profile 20 is embodied in the form of elongated nubs. The profile 20 can also be embodied, for example, as a ribbing, fins, winglets or as an embossing. The profiling 20 ensures that a heat transfer in a flow of the fluid is improved and/or a heat transfer surface is enlarged. The ribbing 20 can be produced in different ways, e.g., by erosion, etching, milling, laser melting processes, embossing, an additional TE insert or ribs.

The outer tube 8 and/or the inner tube 7 can respectively be structured in a one-part or multipart manner. In the case of a two-part structure, the tube is then assembled from an upper part 18 and a lower part 19 in the form of e.g. two half-shells. The upper part 18 and the lower part 19 have the joint seam 21 in a lateral region of the tube, that is, on a short tube wall side.

Accordingly, FIGS. 4 through 7 show in isometric images exemplary embodiments of two-part inner 7 and outer 8 tubes.

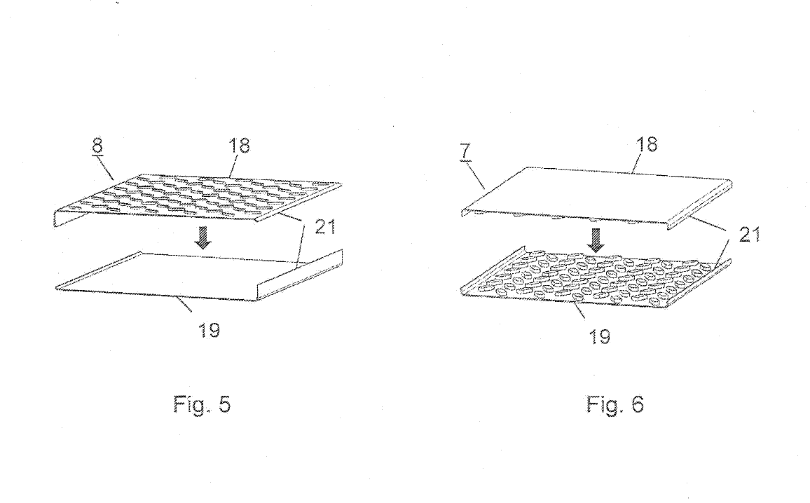

Thus FIG. 4 shows an exemplary embodiment of a two-part outer tube 8 with the joint seam 21 in the center lateral region and FIG. 5 shows an exemplary embodiment of a two-part outer tube 8 with the joint seam 21 in the upper and/or lower lateral region.

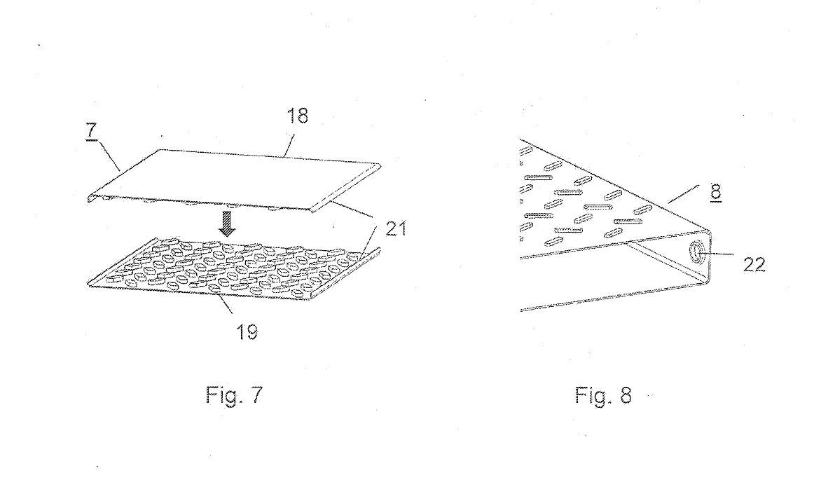

FIG. 6 shows an exemplary embodiment of a two-part inner tube 7 with the joint seam 21 in the center lateral region and FIG. 7 shows an exemplary embodiment of a two-part inner tube 7 with the joint seam 21 on the upper and/or lower lateral region.

The tubes 7, 8 can have the seams 21, regardless of whether they are produced in a one-part or multipart manner.

The tubes 7, 8 can have openings 22 for an electrical connection of the TEM.

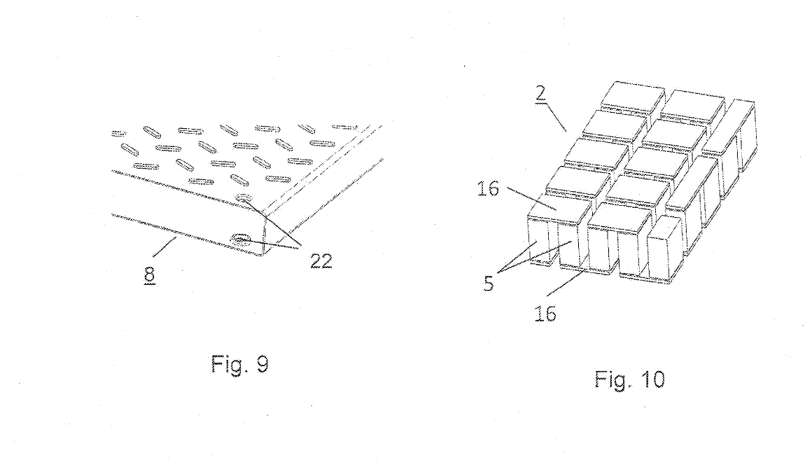

Accordingly, FIG. 8 shows in an isometric partial image an exemplary embodiment of an outer tube 8 with a lateral opening 22. FIG. 9 shows in an isometric partial image an exemplary embodiment of an outer tube 8 with a lower and/or upper opening 22 in the lower and/or upper main surface of the tube 8.

FIG. 10 shows a thermoelectric module (TEM) 2 in an isometric image. The TEM 2 is composed of a plurality of thermoelectrically active (TE-Active) materials 5 and conductors 16. The TE-active materials 5 are arranged spaced apart from one another in one plane. Each conductor 16 is connected to respectively one bottom and/or top of two TE-active materials 5. The conductors 16 can be thin-walled copper sheets, for example.

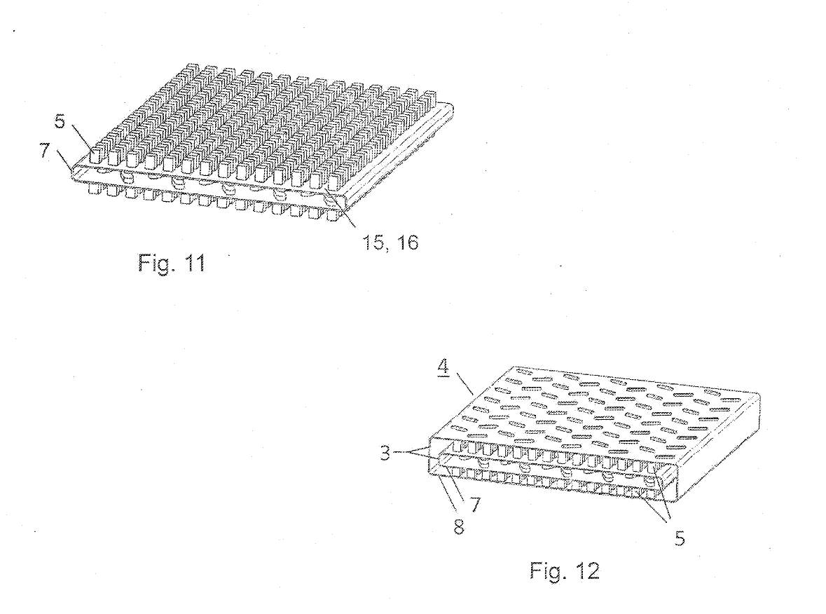

FIG. 11 shows isometrically an inner tube 7, which is equipped on both main surfaces on the outside 6 with TE materials 5. The tube 7 is coated with a nonconductor 15 of an electrically non-conducting ceramic material. The conductors 16 are connected to the ceramic coating 15, e.g., by soldering or sintering.

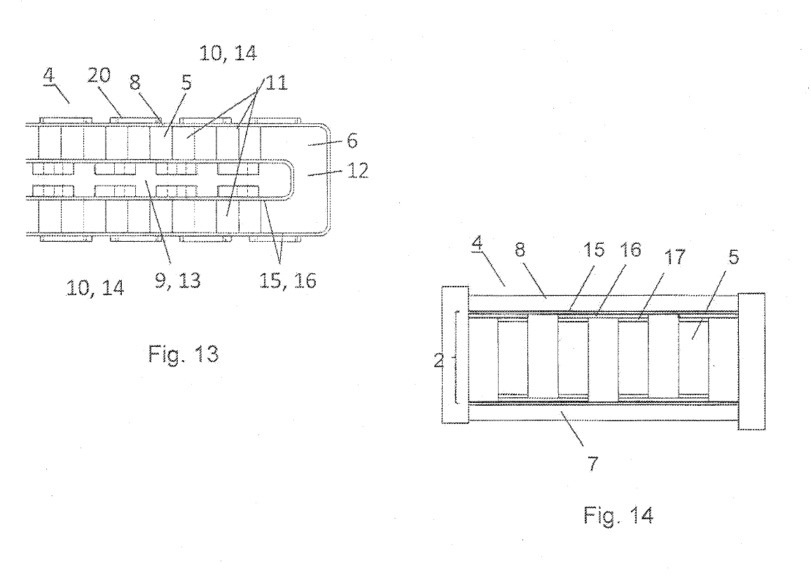

FIG. 12 shows in a further isometric image a complete TEM tube 4. Here the inner tube 7 equipped with TE-active materials 5 explained in connection with FIG. 11 is surrounded by the outer tube 8. The TEM tube 4 is thus composed of the TEM and a two-walled tube 3 of the inner tube 7 and the outer tube 8. The two-walled rectangular tube (3) or flat tube (3) can have rounded corners, as in the exemplary embodiment shown in FIG. 12.

FIG. 13 shows a section of the TEM tube 4 from FIG. 12 in section. The TE materials 5, the intermediate space 6 between the two walls of the TEM tube 4, the outer tube 8, a first fluid 9 (not shown), a second fluid 10 (not shown), upper and/or flat gaps 11 of the intermediate space, a lateral region 12 of the intermediate space, an inner region 13 for the first fluid 9, an outer region 14 for the second fluid 10, the electrically non-conducting material 15, the electrically conducting material 16 and the profile 20 on the outer tube 8 are shown.

The TE materials 5 are located in the upper as well as in the lower flat gap of the intermediate space 11, that is, on the long tube wall side of the TEM tube 4, but not in the lateral region 12, which is located on the short tube wall side. In this respect the TEM tube 4 is composed essentially of two planar TEMs or TEM modules 2, which are located parallel opposite one another, and create the interior 13 located between them, which receives the first 9 of the two fluids 9, 10 and is delimited laterally to the outside. The intermediate space of the lateral region 12 can represent a thermal separation between interior 13 and exterior 14. The intermediate space 6 in addition can be filled with an inert gas or with a non-conducting material, in order to protect the TE materials 5. The non-conducting material can be formed, for example, by a plastic, an adhesive, e.g. on silicone basis or a ceramic.

FIG. 14 shows in a further image in cross section an enlarged section of the TEM tube 4.

The conductors 16 are connected to the TE materials 5, e.g., by soldering and thus interconnect them electrically parallel or in series to one another. A barrier layer 17 can be inserted between a conductor 16 and an actual TE material 5, which barrier layer protects the TE materials 5 or a doping of the TE materials 5 in use.

The axial ends of the TEM tubes 4 can be closed with respect to the intermediate space 6, so that neither the first fluid 9 nor the second fluid 10 can penetrate into the intermediate space 6 and the TEM 2 is encapsulated. This can be carried out via a TEM tube cover 23, which axially closes the intermediate space 6.

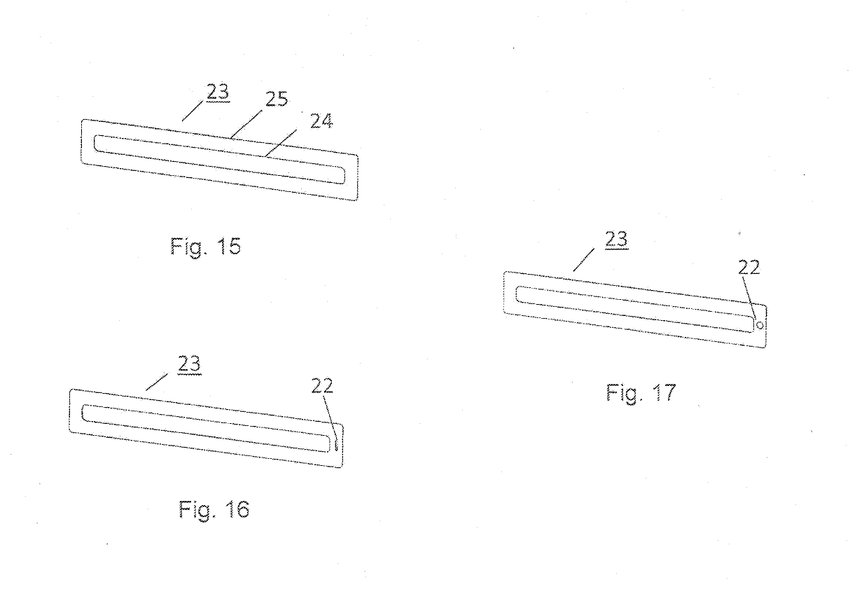

Accordingly, FIGS. 15 through 17 show isometric images of exemplary TEM tube covers 23. The TEM tube cover 23 has an inner contour 24 and an outer contour 25. The TEM tube cover 23 can have openings 22 for the electrical connection of the TEM 2, as can be seen from the exemplary embodiments shown in FIGS. 16 and 17.

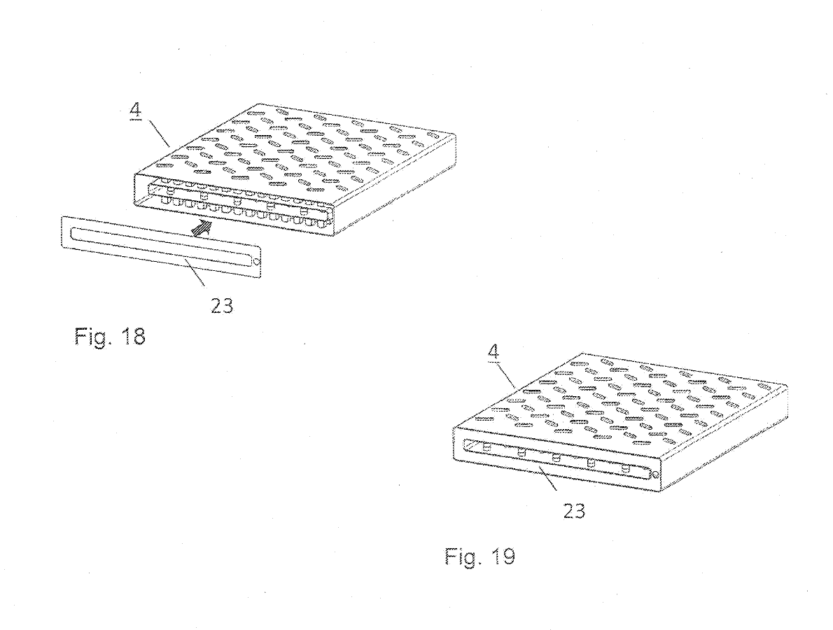

FIGS. 18 and 19 show by way of example a joining of the TEM tube cover 23 to the TEM tube 4 or the TEM tube 4 with joined cover 23.

The inner contour 24 of the TEM tube cover 23 is thereby connected to the inner tube 7, and the outer contour 25 of the TEM tube cover 23 is connected to the outer tube 8. The cover 23 thus ensures an unimpeded flow through of the interior 13 and of the exterior 14 of the TEM tube 4. The cover 23 can be flush with the tube 3 or can be set back with respect to the inner tube 7, when the outer tube 8 is shorter than the inner tube 7. The TEM tube cover 23 can be insulated with respect to the electrical components 16, 5 of the TEM tube 4.

In terms of production engineering, firstly the inner tube 7 can be equipped with the TEM 2 on both sides and subsequently the outer tube 8 can be added. Joined outer tube 8, TEM 2, inner tube 7 and optionally also the TEM tube cover 23 can subsequently be subjected to a heat treatment, e.g., a furnace brazing, so that the components are connected to one another.

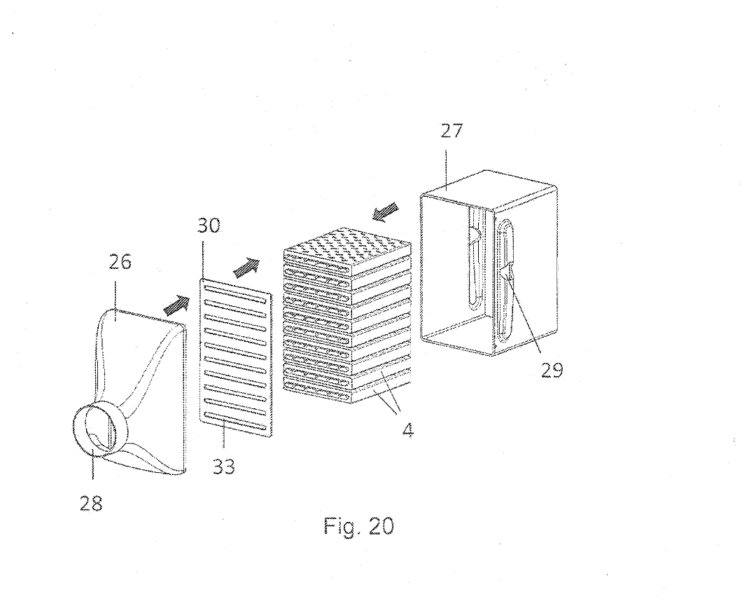

FIG. 20 shows in an isometric exploded view by way of example an assembly of the individual components of thermoelectric generator (TEG). A plurality of TEM tubes 4, a diffuser 26 for the first fluid, a housing 27 for the second fluid, an opening 28 in the diffuser 26, an opening 29 in the housing 27 and a base 30 with openings 33 are shown.

The TEG is composed essentially of a plurality of TEM tubes 4 stacked one of top of the other, as well as bases 30, diffusers 26, a housing 27 and various electrical components such as e.g. lines and/or plug connectors, which connect the TEG outwardly electronically as well as also optionally the TEM tubes 4 in series or parallel to one another. For the electrical connection of the TEG, the diffusers 26 and/or the housing 27 are embodied with openings in this respect. For the sake of clarity, the TEG shown isometrically in FIG. 20 is shown with only one base 30 and one diffuser 26. Likewise only one of the openings 33 and 29 is provided with a reference number. The electronic components are not shown.

It can be seen from FIG. 20 that the TEM tubes 4 are spaced apart from one another and in this respect do not touch one another. The TEM tubes 4 are connected to the openings 33 of the bases 30. The shape of the openings 33 of the bases 30 is designed such that it corresponds to an inner tube cross section of the TEM tubes 4. The bases 30 are connected to the housing 27 and/or to the diffusers 26. The housing 27 and the diffusers 26 can be connected to one another.

The first fluid can be supplied to the TEG shown by way of example in FIG. 20 via the opening 28 in the diffuser 26. Subsequently, it can be guided into the interiors of the TEM tubes 4. Subsequently, the first fluid can reach the second diffuser 26 and subsequently can be discharged via its opening 28. The second fluid can communicate with the TEG via the opening 29 in the housing 27. The second fluid can flow around the connected outer chamber of the TEM 4 tubes in the housing 27, and can be discharged again via the opposite opening 29 in the housing 27.

The bases 30 separate a region of the first fluid in the TEG from a region of the second fluid.

It is not shown in FIG. 20 that the electrical connection of the TEM tubes 4, as already explained, can be carried out via openings of the lateral region of the TEM tubes and/or via openings of the upper and lower region of the TEM tubes or in the axial direction. In this case this can also be carried out via the TEM tube cover.

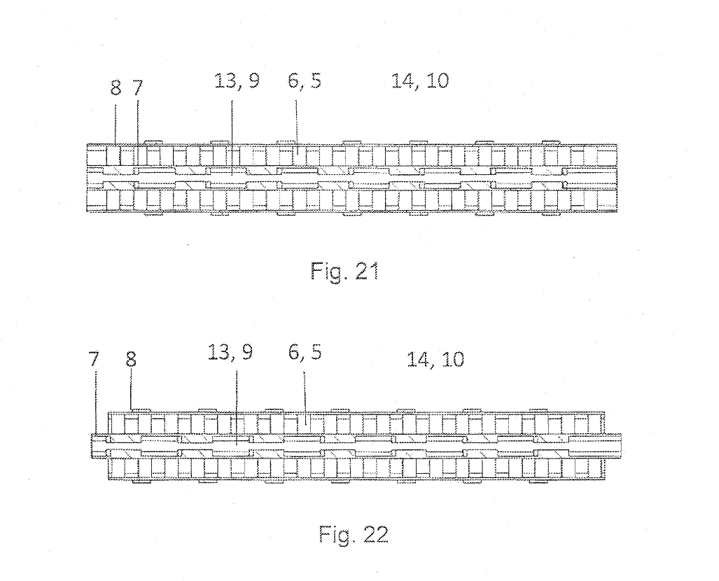

The inner tube of the TEM tube can be flush with the outer tube. The outer tube can also be set back with respect to the inner tube. Corresponding exemplary embodiments are illustrated in FIGS. 21 and 22, which respectively show a longitudinal section through an inner 7 and an outer 8 tube of an exemplary TEM tube.

Thus the sectional image of the exemplary embodiment in FIG. 21 shows that inner 7 and outer 8 tube are arranged in a flush manner in the longitudinal direction. In contrast, in the exemplary embodiment shown in FIG. 22, the inner tube 7 projects in the longitudinal direction with respect to the outer tube 8.

Depending on how the outer tube and inner tube are designed, and whether a TEM tube cover is used, and also how the electrical connection of the TEM tubes is accomplished, an inner tube base and/or an outer tube base is used

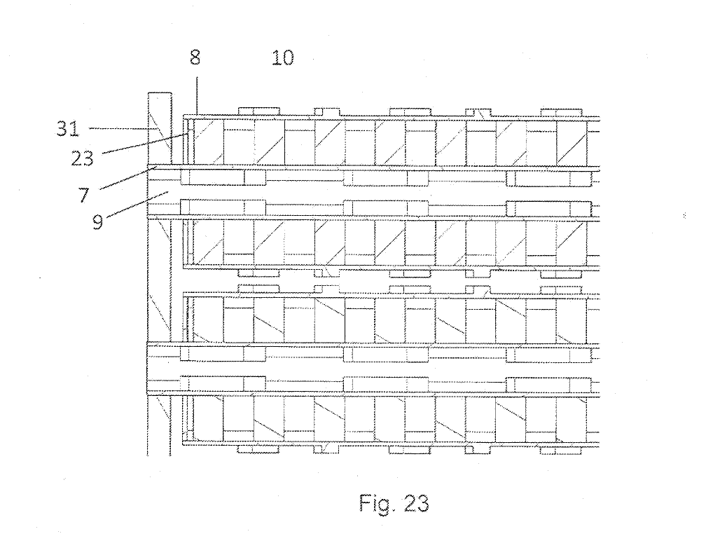

Accordingly, FIGS. 23 through 27 show different exemplary embodiments of bases 30, which are embodied according to the arrangement of inner tube 7 to outer tube 8 as an inner tube base 31 and/or an outer tube base 32.

FIG. 23 shows in a sectional image an embodiment of the base as an inner tube base 31 in connection with two inner tubes 7 projecting with respect to the outer tubes 8. The TEM tubes are provided with covers 23. The inner tube base 31 is spaced apart from the outer tubes 8 and is connected via its openings to the inner tubes 7. The inner tube base 31 separates the first fluid 9 and the second fluid 10.

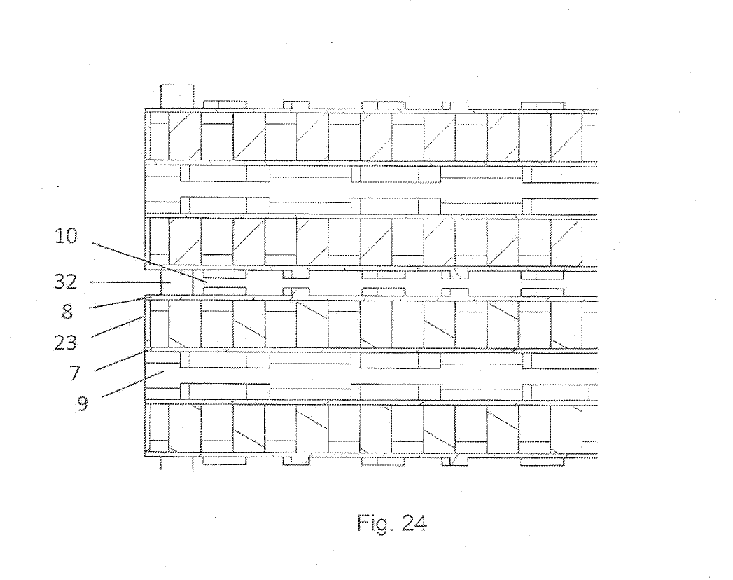

FIG. 24 shows in a sectional image an embodiment of the base as an outer tube base 32 in connection with two outer tubes 8 arranged aligned with respect to the inner tubes 7. The TEM tubes here in turn are provided with covers 23. The outer tube base 32 can be connected to the outer tubes 8 via the openings 33 thereof and separates the first fluid 9 and the second fluid 10.

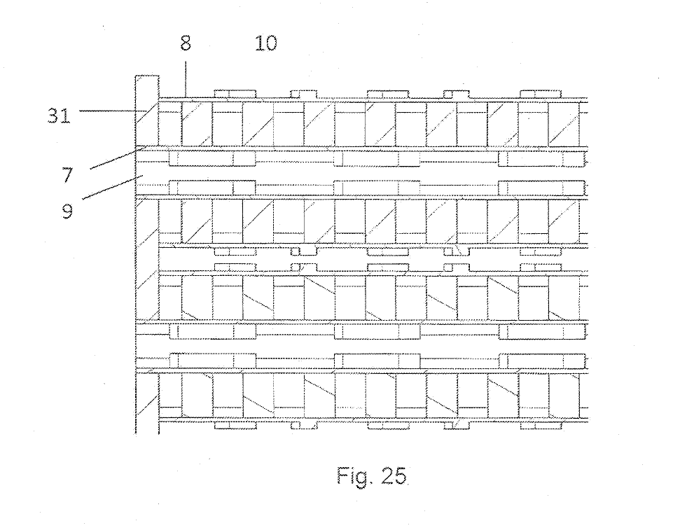

FIG. 25 shows in a sectional image a further embodiment of the base as inner tube base 31 in connection with two inner tubes 7 projecting with respect to the outer tubes 8. Since there is no spacing between the inner tube base 31 and the outer tubes 8, the inner tube base 31 is also connected to the outer tube 8. Thus covers 23 can be omitted according to this embodiment. In turn the inner tube base 31 separates the first fluid 9 from the second fluid 10.

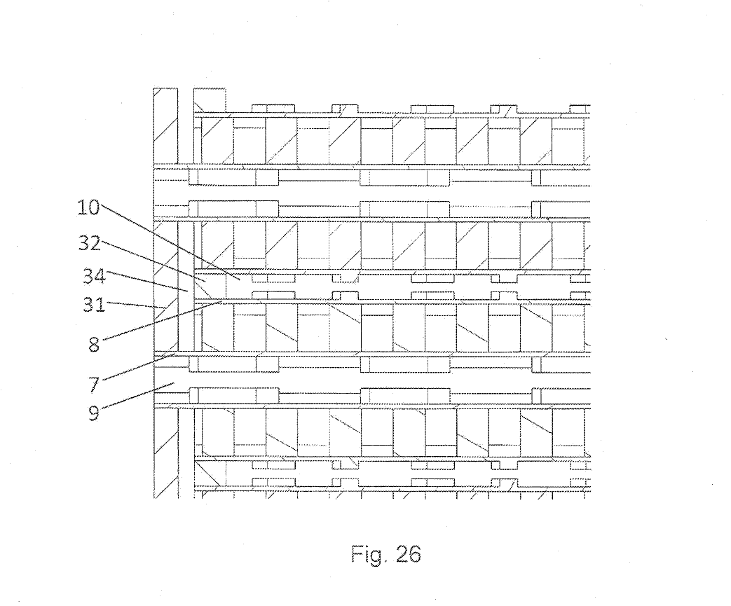

FIG. 26 shows an exemplary embodiment with the use of an inner tube base 31 as well as of an outer tube base 32. If the outer tube base 32 as well as the inner tube base 31 is used, an intermediate space 34 is formed between these two bases 31 and 32, which intermediate space does not receive the first fluid 9 or the second fluid 10. This intermediate space 34 is suitable, for example, for the electrical connection of the TEM tubes and/or of the TEG. This embodiment shown in FIG. 26 can be realized with or without cover 23.

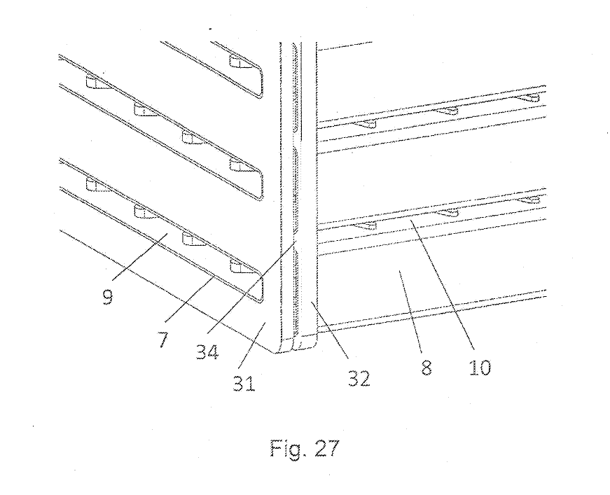

FIG. 27 shows the exemplary embodiment explained in connection with FIG. 26 for easier comprehension once again in an isometric image. Here the intermediate space 34, not flowed through, formed by the inner tube base 31 and the outer tube base 32 can be clearly seen.

The various possibilities of an electrical connection of individual thermoelectric modules are explained below.

In general, the TE-active materials or thermoelectric modules can be interconnected to one another in series and/or in a parallel manner in the lower and upper gap of the intermediate space in a TEM tube. The TE-active materials of the lower gap of the intermediate space can be connected to the TE-active materials of the upper gap of the intermediate space in series or in a parallel manner. The TEM tubes can be connected to one another in series and/or in a parallel manner. The electrically conducting connections outside the TEM tubes, which are in contact with the first fluid and/or the second fluid, if applicable must be electrically insulated. The electrical connection can be carried out in the region of the first fluid, of the second fluid or in the neutral region of the base intermediate space between an outer tube base and an inner tube base. The electrical connection can be non-positive, positive or by adhesive force.

The TE materials of the upper and lower region of the intermediate space can be electrically connected to one another via the conductors thereof and a conductor connector. Optionally, this can also be realized via insert conductors or insert bushings. The conductor connectors are preferably a thin-walled copper sheet.

Different embodiments of the electrical connection, which can be combined with one another, are explained in greater detail below.

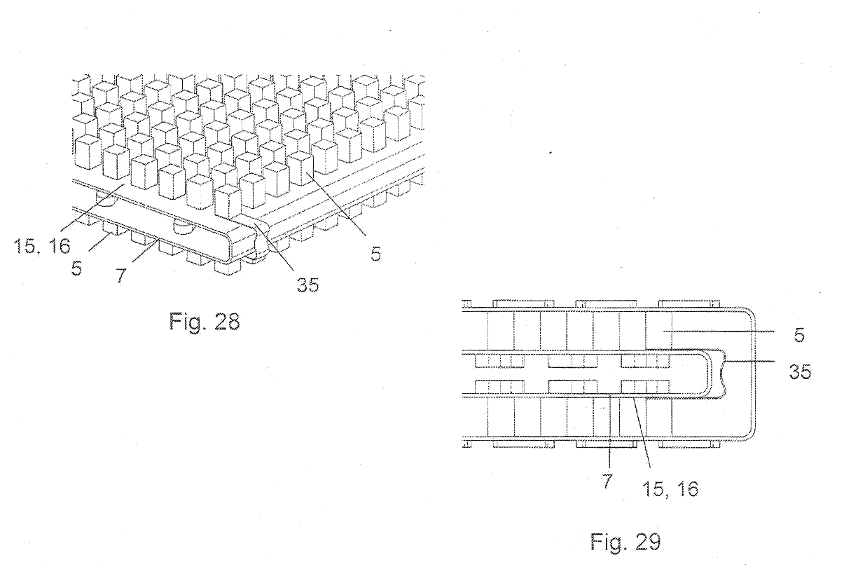

The following FIGS. 28 through 45 show different exemplary embodiments of conductor connections and the connection possibilities thereof.

Thus FIG. 28 shows in an isometric image a section of an exemplary inner tube 7, which is equipped with TE-active materials 5 on opposite main surfaces. In their totality, the TE-active materials 5 arranged in an adjacent manner on a main surface form the thermoelectric module 2. In FIG. 28 a conductor connection 35 of the upper and lower gap of the intermediate space is shown. The upper and the lower thermoelectric module 5 of a TEM tube are thus connected to one another in an electrically conducting manner. As is shown in FIG. 28, the conductor connector 35 can project in part from the inner tube 7 and is always insulated with respect to the inner tube 7.

This can be seen more clearly based on the sectional image shown in FIG. 29 of the section of the TEM tube from FIG. 28. The conductor connection 35 of the upper and lower gap of the intermediate space 11 projects in the lateral region of the intermediate space.

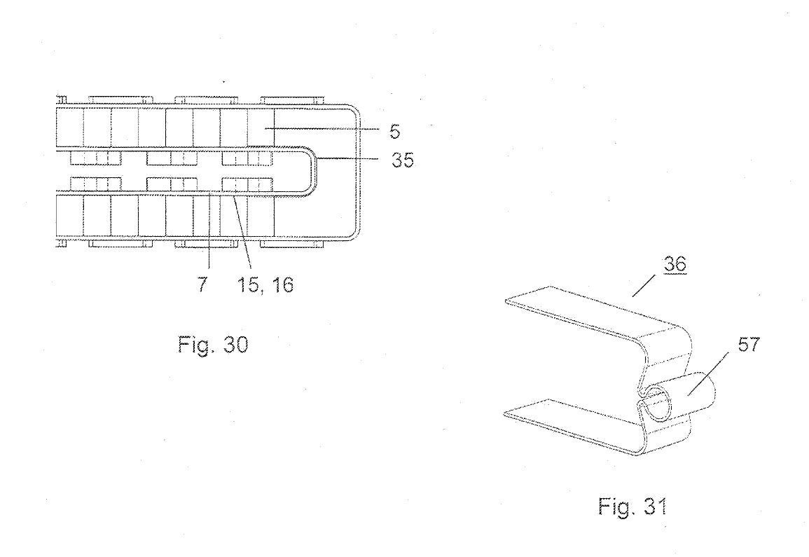

In contrast thereto, the partial sectional image in FIG. 30 shows an exemplary embodiment of the conductor connection 35 of the upper and lower gap of the intermediate space 11, which is connected over the whole surface to the inner tube 7.

The conductor connector can furthermore have a bushing as is illustrated based on the isometric image of an exemplary embodiment of a conductor connector 36 in FIG. 31. A bushing 57 here serves as an electrical connection element in order to electrically connect the TEM tube via lines, cable, plugs or the like externally. The bushing 57 can have a conical course or have snap-in elements or barbed hooks or clamps in order to prevent a detachment of a line or a plug.

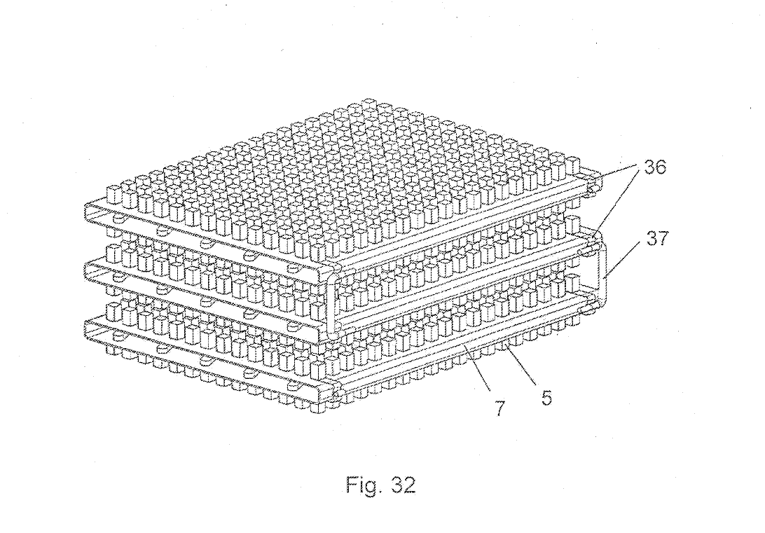

FIG. 32 shows in an isometric image an interconnection option of TEM tubes via conductor connections 36 with bushing 57. In the exemplary embodiment shown in FIG. 32, electrical lines 37, for example, electrically insulated copper cables, are guided through bushings 57 of the conductor connections 36 in order to thus electrically connect three TEM tubes stacked one on top of the other. The TEM tubes are shown in FIG. 32 without outer tubes. More or fewer than the three TEM tubes shown can also be connected. The conductor connection 36 with bushing 37 thus fulfills the double function of electrically interconnecting the TE modules of one and the same TEM tube as well as a plurality of TEM tubes.

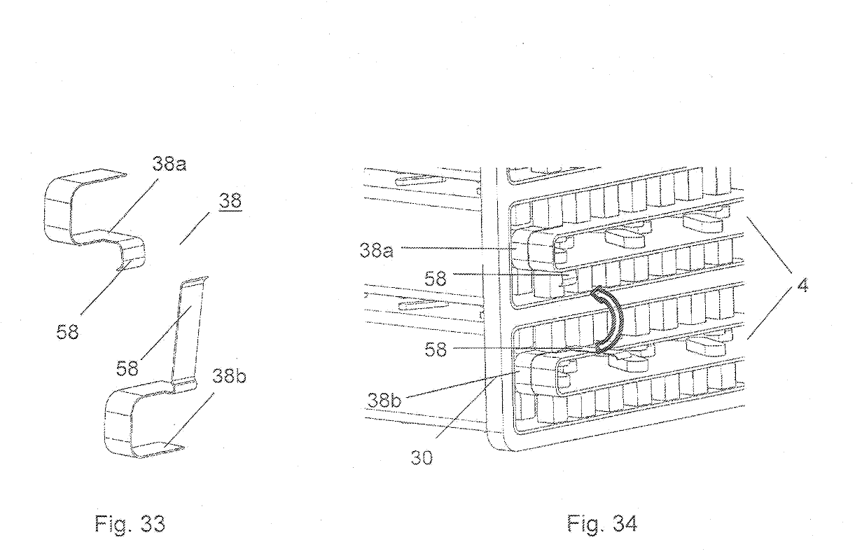

The isometric image in FIG. 33 shows an exemplary embodiment of a conductor connector 38 in a two-part form. This two-part TEM tube-TEM tube conductor connection 38 is embodied in order to connect two TEM tubes electrically to one another and in this respect has additional shapes 58, which allow a first part 38a and a second part 38b of the conductor connection 38 to be connected to one another.

Accordingly, FIG. 34 shows a use of the exemplary conductor connection 38 in an isometric partial image. Both parts 38a and 38b are placed onto respectively one inner tube of two TEM tubes 4. An arrow indicates a step for joining the parts 38a and 38b by means of the shapes 58 of both parts 38a, 38b in order to thus produce the electrical interconnection of the TEM tubes 4.

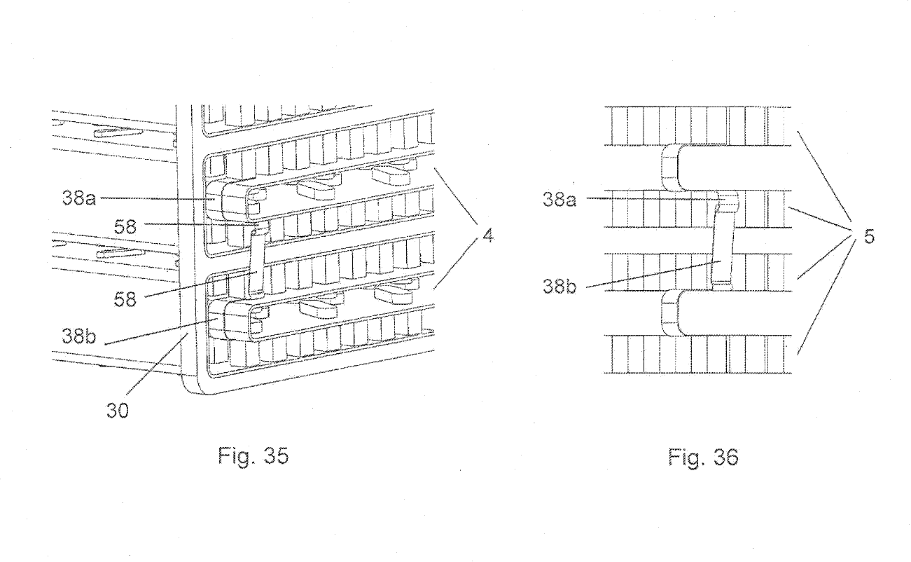

FIG. 35 shows in an isometric image a state after concluded step according to the image in FIG. 34. Two TEM tubes 4 are shown interconnected by means of the two-part TEM tube-TEM tube conductor connection 38. The two-part TEM tube-TEM tube conductor connection 38 is suitable for the electrical interconnection of TEM tubes with inner tubes projecting with respect to the outer tubes.

For clarification, the image in FIG. 36 shows again in an enlarged view the functionality of the two-part connector 38 for the interconnection of TEMs.

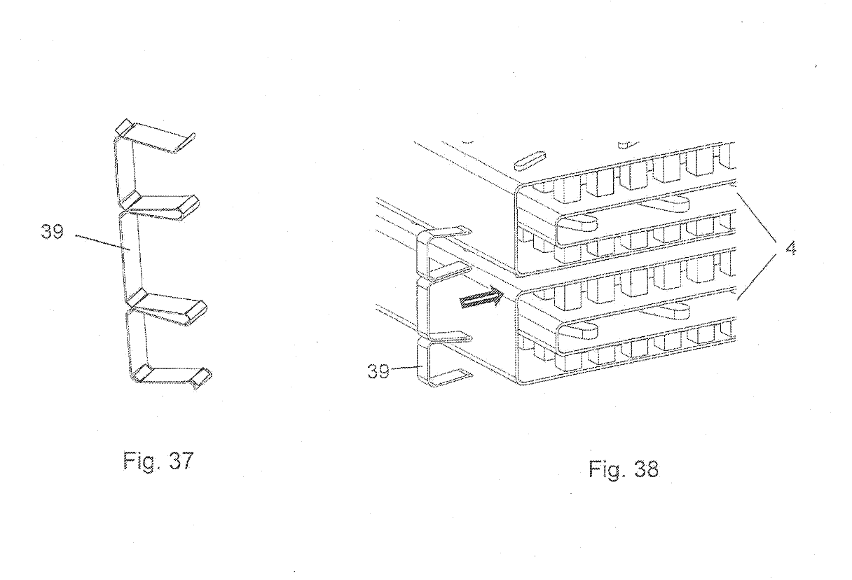

FIG. 37 shows in an isometric image a one-part TEM tube-TEM tube conductor connection 39.

A step for the use of the TEM tube-TEM tube conductor connection 39 is shown based on the isometric image in FIG. 38. The conductor connector 39 can in a one-part form connect two TEM tubes 4 electrically to one another and is designed in a similar manner to a clamp.

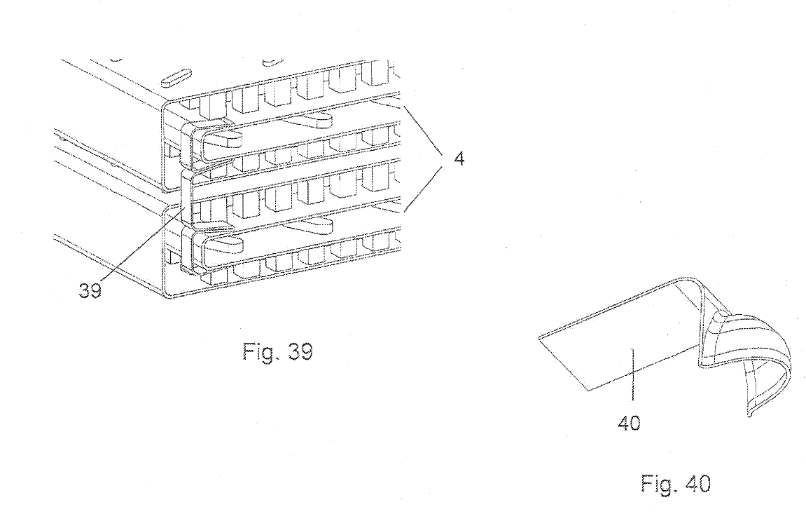

FIG. 39 shows accordingly in an isometric image the joined one-part TEM tube-TEM tube conductor connection 39. The electrical connector 39 is also suitable for the electrical interconnection of TEM tubes to inner tubes projecting with respect to the outer tubes.

FIGS. 40 through 45 show in isometric images further embodiment possibilities of the electrical connector suggested here for the interconnection of thermoelectric modules and their use positions on TEM tubes.

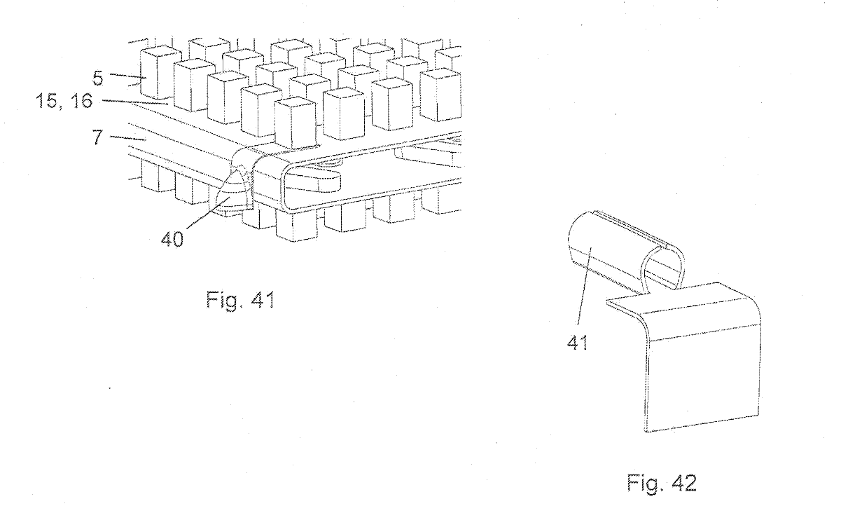

Thus FIGS. 40 and 41 show an exemplary embodiment of an insert conductor 48 or the insert conductor 40 in connection with thermoelectric modules of a TEM tube.

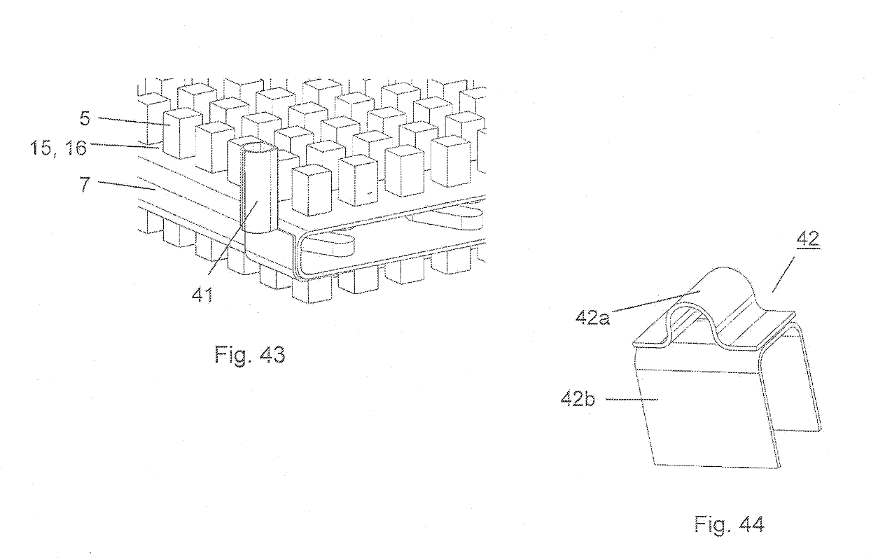

FIGS. 42 and 43 show an exemplary embodiment of an insert bushing 41 or the insert bushing 41 in connection with thermoelectric modules of a TEM tube.

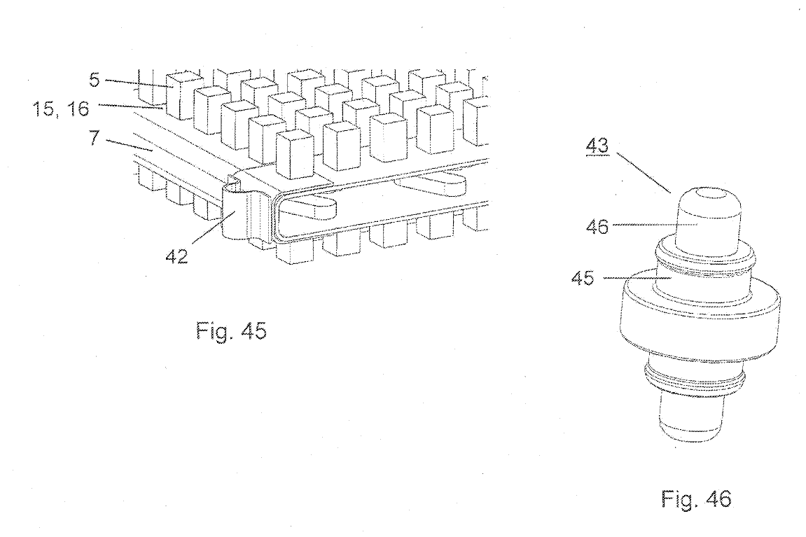

FIG. 44 shows an exemplary embodiment of a two-part insert bushing 42 with a first part 42a and a second part 42b. FIG. 45 shows the two-part insert bushing 42 in connection with thermoelectric modules of a TEM tube.

The one-part or multipart conductor connectors 40, 41, 42 shown by way of example in FIGS. 40 through 45 can have moldings, e.g., expansions, hollows, bushings, bends, etc., which render possible an insertion or plugging in of TEM tube-external lines or plugs.

A further option for the electrically conducting connection of TEM tubes is a TEM tube plug connector.

FIG. 46 shows in an isometric image a TEM tube plug connector 43 according to an exemplary embodiment of the invention. The TEM tube plug connector 43 has a nonconductor 45 and a conductor 46.

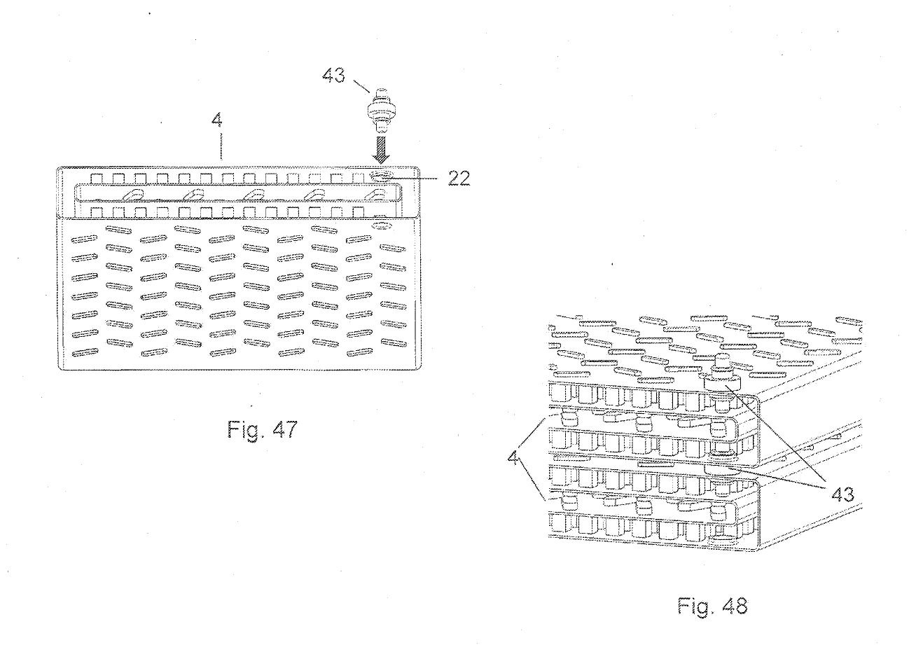

FIG. 47 shows in an isometric image on the basis of an arrow a step for joining the TEM tube plug connector 43.

The TEM tube plug connector 43 interconnects two TEM tubes 4 electrically to one another. For this purpose, the two ends of the TEM tube plug connector 43 are inserted into the openings 22 of the two TEM tubes 4. The TEM tube plug connector 43 has the interior conducting core 46 and the non-conducting sheath 45. The conducting core 46 makes contact with conducting components, e.g., conductors or conductor connections, of the TEM of the TEM tubes 4. The non-conducting sheath 45 electrically insulates in the external region and in the inlet point 22 of the TEM tube plug connector 43 into the tube. The opening 22 thereby becomes fluid-tight. In addition, a sealing adhesive, e.g., silicone, can be applied.

FIG. 48 shows in an isometric image in section an interconnection of TEM tubes 4 via the TEM tube plug connector 43.

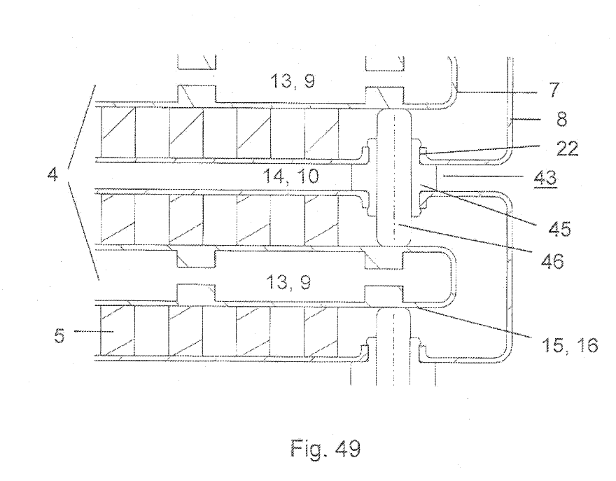

In FIG. 49 the interconnection of the TEM tubes 4 via the TEM tube plug connector 43 is shown in section.

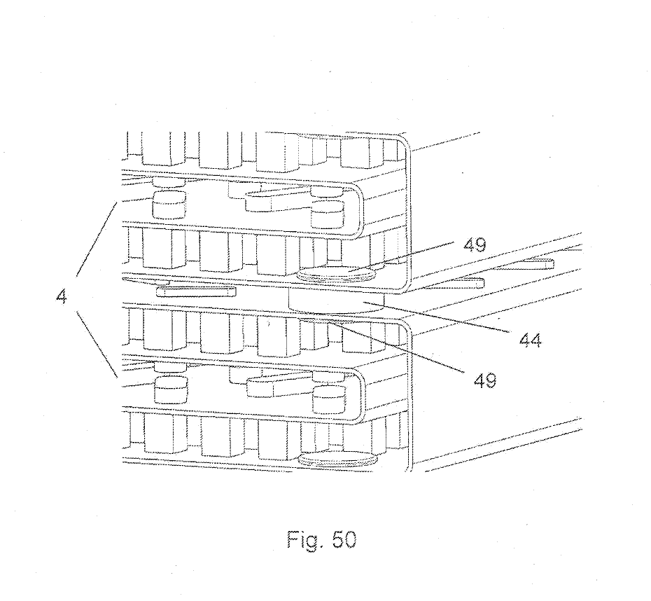

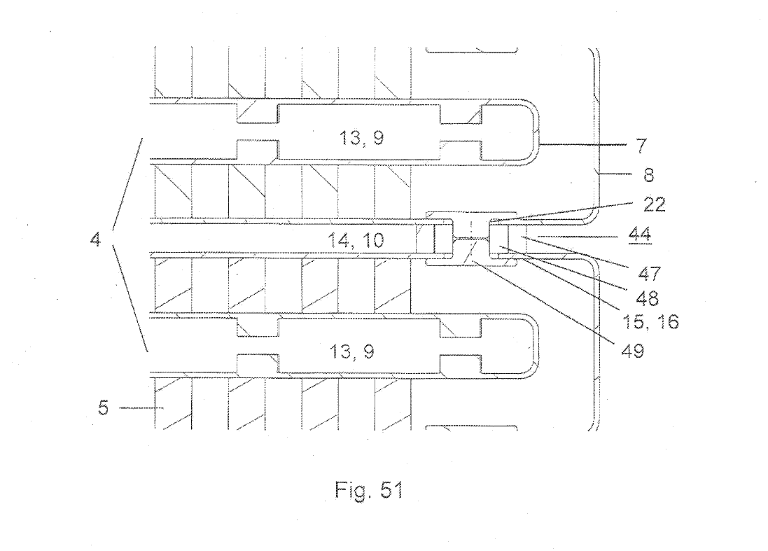

Furthermore, TEM tubes 4 can be interconnected by means of a conductor jointing sleeve, as is shown in FIG. 50 based on an exemplary embodiment of a conductor jointing sleeve 44, which comprises two conductor prongs 49. FIG. 51 shows the interconnection of the TEM tubes 4 via the conductor jointing sleeve 44 in section. The electric conductor 49 projects out of the opening 22 of the tube 8 in a prong-like manner into the outer region 14. The electric conductor 49 is connected to the tube 8 in a fluid-tight and electrically insulated manner. The electric conductor 49 is interconnected to the electrical system 16 of the TEM. The conductor connection sleeve 44 has an interior conducting sleeve 48 and a non-conducting sheath 47. The prongs of the electric conductors 49 of two adjacent TEM tubes 4 are inserted into the interior conducting sleeve 48 of the conductor connecting sleeve 44 and are thus electrically connected to one another. The non-conducting sheath 47 electrically insulates in the outer region 14 the conductor connecting sleeve 44. In addition, a sealing adhesive, e.g., silicone, can be applied between the conductor connecting sleeve 44 and the tube 8.

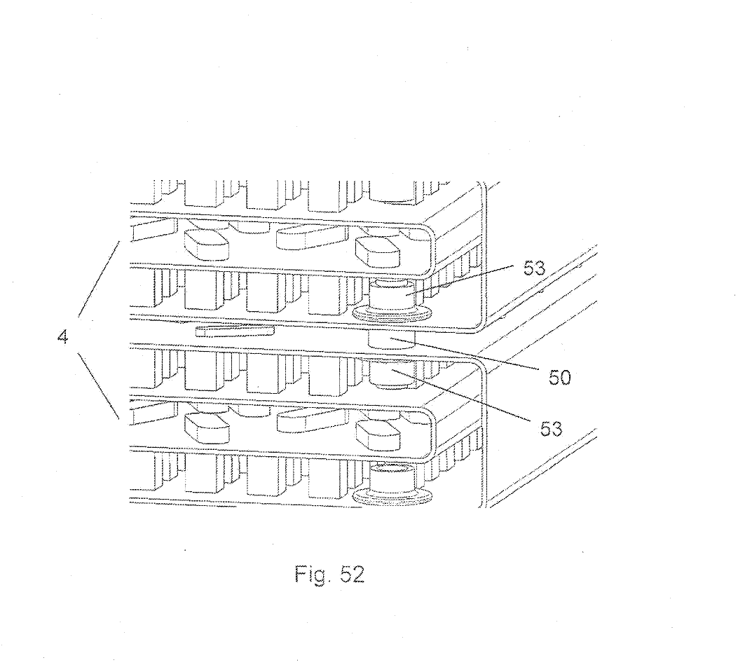

FIG. 52 shows in an isometric image a further possibility for the interconnection of TEM tubes 4 via a conductor pin 50 to a conductor bushing 53.

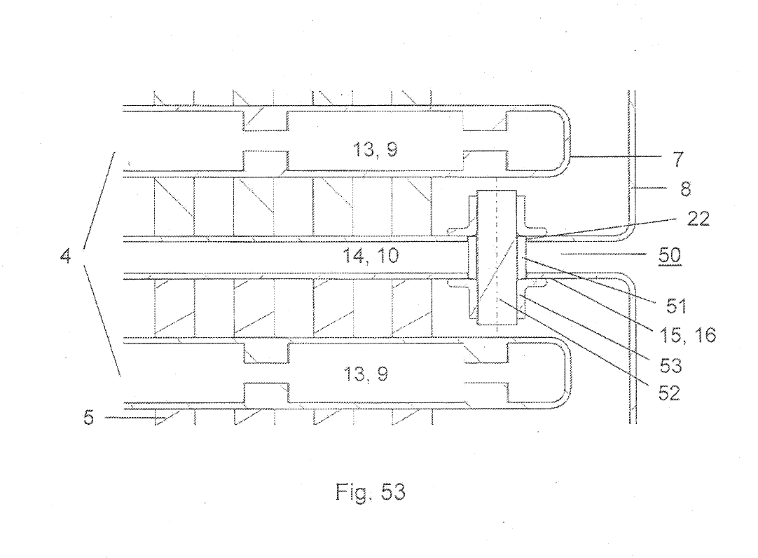

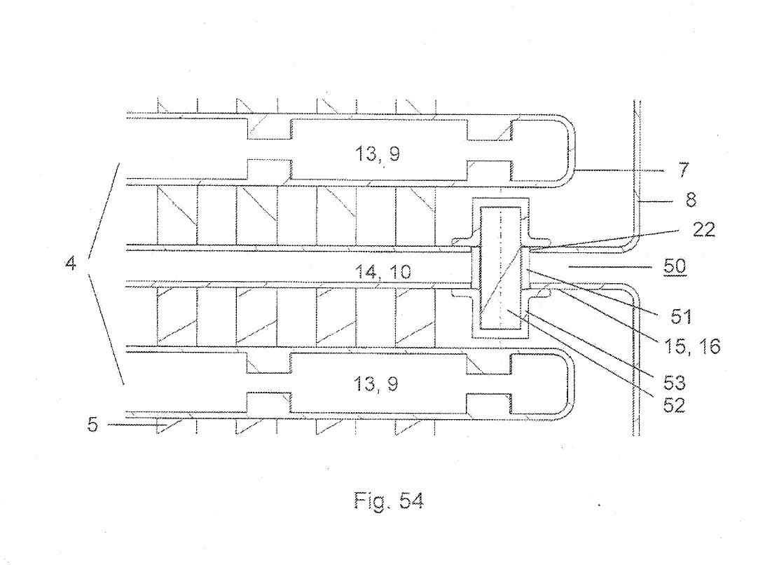

FIGS. 53 and 54 show in a sectional view two exemplary embodiments for an interconnection of TEM tubes 4 via a conductor pin 50.

According to the exemplary embodiments shown in FIGS. 52 and 53, the conductor bushing 53 has a contact hole or blind hole and is attached concentrically to the opening 22 of the tube 8 in the intermediate space between the inner tube 7 and the outer tube 8. The conductor bushing 53 is connected to the tube 8 in a fluid-tight and electrically insulated manner. The conductor bushing 53 is connected to the electrical system 16 of the TEM. The conductor pin 50 has an interior conducting core 52 and a non-conducting sheath 51. The conducing core 52 contacts with the conductor bushings 53 the TEMs of two adjacent TEM tubes 4. For this purpose the two ends of the conductor pin 50 are inserted into the openings 22 of the two TEM tubes 4. The non-conducting sheath 51 electrically insulates the conductor pin 50 in the outer region 14. In addition, a sealing adhesive, e.g. silicone, can be applied between the conductor pin 50 and the tube 8.

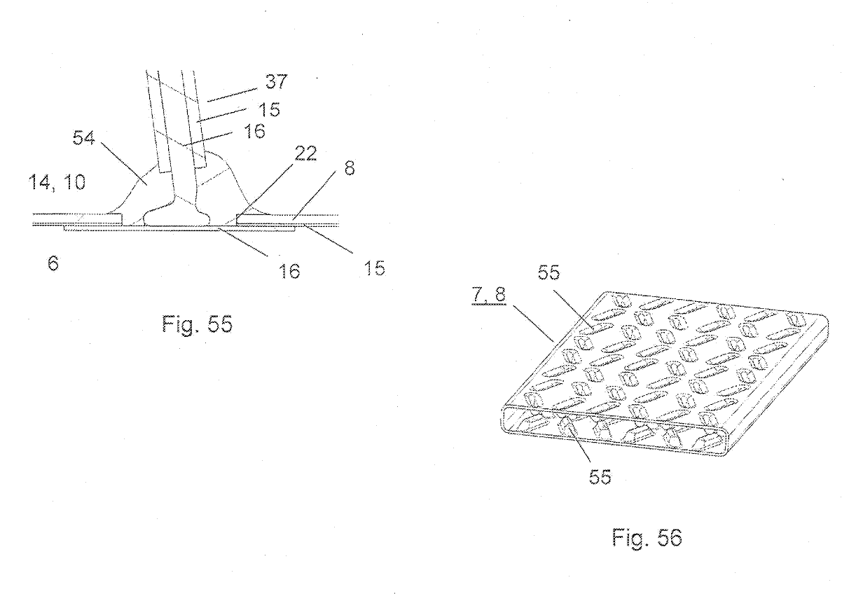

FIG. 55 shows in section an alternative possibility for connecting TEM tubes via a soldered cable 37.

According to the exemplary embodiment shown in FIG. 55, an electric conductor 16 covers the opening 22 of the tube 8 on the intermediate space side 6. The electric conductor 16 is connected to the tube 8 in a fluid-tight and electrically insulated manner. The electric conductor 16 is connected to the TE electrical system 16 of the TEM in the TEM tube. The conducting core 16 of the electric cable 37 is connected on the outside 14 to the electric conductor 16 in an electrically conducting manner, e.g., by soldering. The non-conducting sheath 15 of the electric cable 37 insulates electrically the electric cable 37 in the outer region 14. An insulating compound 54, e.g., a sealing adhesive on a silicone basis, in the opening region 22 electrically insulates the contact region of the cable 37 with the electric conductor 16 outwardly 14.

FIGS. 56 through 59 show isometrically or in section shaping options for the tube profiling with the object of improving the electrical connection of the TE-active materials.

FIG. 56 shows in an isometric image a tube profiling 55 produced by shaping.

The profiling 55 produced by shaping, e.g., embossing, in the tube 7, 8 can make the connection of the TEM, and in particular the TE-active materials and the electric connecting conductor thereof, more difficult in the TEM tube. The intermediate space-side surface of the tube 7, 8 and in particular the shaped profiling 55 thereof, can in this case be provided with a filler material.

A corresponding exemplary embodiment of a filler material 56 for filling the shaped tube profiling 55 is shown in FIG. 57. The filler material 56 can be, e.g., solder, a paste, a poured metal, a poured plastic, a poured ceramic or a ceramic coating and a layer or adhesive. The filler 56 is embodied in order to create an approximately flat connection surface for the TEM.

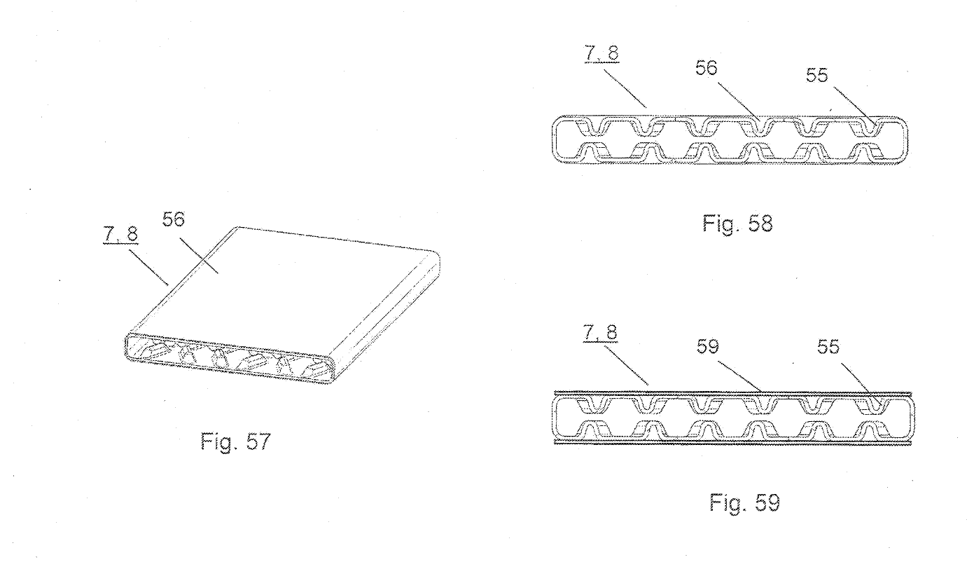

FIG. 58 shows the exemplary embodiment of the filled 56 shaped tube profiling 55 in a sectional view.

Alternatively and/or additionally, the intermediate space-side surface of the tube 7, 8 can be covered by a flat metal sheet 59, as is shown in section in FIG. 59 based on an exemplary embodiment. The metal sheet 59 here creates a connection surface for the TEM. The cover sheet 59 can be firmly connected to the filler material and/or the tube 7, 8.

A design and a structure of the thermoelectric module, an incorporation of the thermoelectric module into a thermoelectric generator and an electrical connection of the thermoelectric modules and the generator have thus been explained in connection with the previously described figures.

The exemplary embodiments described are selected merely by way of example and can be combined with one another.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A thermoelectric unit with the following features:
a first thermoelectric module that has a plurality of thermoelectric elements interconnected to one another, the first thermoelectric module being arranged between a main surface of an inner flat tube and a main surface of an outer flat tube of a double-walled cooling tube;
a second thermoelectric module that has a plurality of thermoelectric elements interconnected to one another, the second thermoelectric module being arranged between a further main surface of the inner flat tube and a further main surface of the outer flat tube of the double-walled cooling tube and/or between a main surface of an inner flat tube and a main surface of an outer flat tube of a further double-walled cooling tube; and
an electrical connector configured to connect the first thermoelectric module to the second thermoelectric module in an electrically conducting manner.

2. The thermoelectric unit according to claim 1, wherein the inner flat tube of the double-walled cooling tube has a greater length than the outer flat tube of the double-walled cooling tube and the inner flat tube of the further double-walled cooling tube has a greater length than the outer flat tube of the further double-walled cooling tube such that at least on one side the ends of the inner flat tubes project beyond corresponding ends of the outer flat tubes, and wherein the electrical connector extends from the projecting end of the inner tube of the double-walled cooling tube towards the projecting end of the inner tube of the further double-walled cooling tube.

3. The thermoelectric unit according to claim 1, wherein the electrical connector is embodied as a one-part clamp, which laterally spans the inner flat tube on a lateral surface of the double-walled cooling tube, wherein a first end of the connector contacts the first thermoelectric module of the double walled cooling tube and a second end or an intermediate contact of the connector contacts the further thermoelectric module of the double-walled cooling tube.

4. The thermoelectric unit according to claim 1, wherein the electrical connector is a one-part multiple connector clamp that laterally spans the inner flat tube of the double-walled cooling tube and the inner flat tube of the at least one further double-walled cooling tube on one lateral surface, and wherein the multiple connector clamp is configured to connect two thermoelectric modules assigned to the double-walled cooling tube to at least one thermoelectric module of a further double-walled cooling tube.

5. The thermoelectric unit according to claim 1, wherein the electrical connector is a multipart clamp, of which a first part spans or covers a lateral surface of the inner flat tube of the double-walled cooling tube and at least one second part spans or covers the inner flat tube of a further double-walled cooling tube on a lateral surface, and wherein the first part and the second part is connectable positively in order to connect in an electrically conducting manner at least one thermoelectric module assigned to the double-walled cooling tube to at least one thermoelectric module assigned to the further double-walled cooling tube.

6. The thermoelectric unit according to claim 1, wherein the electrical connector is spanned by a narrow side of the inner tube and has a bushing in the region of an subsidiary surface of the inner tube connecting the main surfaces of the inner tube, which bushing is configured to be connectable to an insert conductor in an electrically conducting manner.

7. The thermoelectric unit according to claim 1, wherein the outer flat tube of the double-walled cooling tube has a first opening and, on a main surface of the outer flat tube of the further double-walled cooling tube, has a second opening, which is arranged at a position lying opposite the first opening, and wherein the electrical connector is a pin plug that is guided through the first opening and the second opening.

8. The thermoelectric unit according to claim 7, wherein the pin plug has a non-conducting sheath.

9. The thermoelectric unit according to claim 1, wherein the electrical connector has a first part, which is configured as a prong connectable to the thermoelectric module in an electrically conducting manner, which prong projects out of an opening of a main surface of the outer flat tube of the double-walled cooling tube, and wherein the electrical connector has a second part, which is configured as an electrically conducting prong, wherein the second part is connectable to a second thermoelectric module in a conducting manner, which is assigned to a further double-walled cooling tube, and the second part projects out of an opening of a main surface of the outer flat tube of the further double-walled cooling tube, and wherein the first and the second part of the electrical connector are in electrically conducting contact with one another.

10. The thermoelectric unit according to claim 1, wherein the electrical connector is a cable, an end of which is connectable through an opening of a main surface of the outer flat tube of the double-walled cooling tube to the thermoelectric module in an adhesive and electrically conducting manner.
